(19) United States
(12) Patent Application Publication
(10) Pub. No.: US 2019/0288055 A1
(43) Pub. Date: Sep. 19, 2019

(54) DISPLAY DEVICE

(71) Applicant: Sharp Kabushiki Kaisha, Sakai City, Osaka (JP)

(72) Inventors: Tamotsu SAKAI, Sakai City (JP); Fumiyuki KOBAYASHI, Sakai City (JP)

(21) Appl. No.: 16/468,400

(22) PCT Filed: Sep. 29, 2017
(86) PCT No.: PCT/JP2017/035586

§ 371 Date: Jun. 11, 2019

(51) Int. Cl. H01L 27/32; G09G 3/3225; G09G 3/3266

(52) U.S. Cl. CPC H01L 27/3276; H01L 27/3262; H01L 27/1214; G09G 3/3225; G09G 3/3266; H01L 27/3265

(57) ABSTRACT

In a pixel circuit of a display device that includes an electro-optical element and a driving transistor, when a connection wiring line formed in a wiring line layer closer to a wiring line layer in which a first electrode of the electro-optical element is formed than a wiring line layer in which a control electrode of the driving transistor is formed is connected to the control electrode of the driving transistor, the first electrode of the electro-optical element is disposed so as not to overlap the connection wiring line in a plan view. In this way, a coupling capacitance between a node connected to the control electrode of the driving transistor and the first electrode of the electro-optical element is reduced, a step response of the display device is prevented, and power consumption of the display device is reduced.

### TECHNICAL FIELD

The disclosure relates to a display device, and more particularly, to a display device including a pixel circuit including an electro-optical element.

### BACKGROUND ART

Organic Electro Luminescence (hereinafter referred to as “EL”) display devices including pixel circuits including organic EL elements have recently been coming into practical use. The pixel circuit of the organic EL display device includes a driving transistor, a writing control transistor, and the like in addition to the organic EL element. A thin film transistor (hereinafter referred to as a TFT) is used in these transistors. The organic EL element is a kind of an electro-optical element and emits light at brightness according to the amount of flowing current. The driving transistor is provided in series with the organic EL element, and controls the amount of current flowing through the organic EL element.

Variation and fluctuation occur in characteristics of the organic EL element and the driving transistor. Thus, variation and fluctuation in characteristics of these elements need to be compensated in order to perform higher picture quality display in the organic EL display device. For the organic EL display device, a method for compensating a characteristic of an element inside a pixel circuit and a method for compensating a characteristic of an element outside a pixel circuit are known. In the former method, processing of initializing a voltage of a control electrode of a driving transistor to a predetermined level may be performed before a voltage (hereinafter referred to as a data voltage) according to an image signal is written to a pixel circuit. In this case, an initialization transistor is provided in the pixel circuit.

Many circuits have been proposed as pixel circuits including organic EL elements. FIGS. 12 and 13 are circuit diagrams of a known pixel circuit. A pixel circuit 91 illustrated in FIG. 12 includes an organic EL element L1, six TFTs: M1 to M6, and a capacitance C1. The TFT: M1 functions as a driving transistor. The TFT: M5 functions as a writing control transistor. The TFT: M3 functions as an initialization transistor.

A pixel circuit 92 illustrated in FIG. 13 includes an organic EL element L1, seven TFTs: M1 to M7, and a capacitance C1. The pixel circuit 92 includes the TFT: M7 added to the pixel circuit 91. The TFT: M7 functions as a second initialization transistor that initializes a voltage of an anode electrode of the organic EL element L1. A pixel circuit including a second initialization transistor is described in PTL 1, for example.

### CITATION LIST

### Patent Literature

PTL 1: JP 2010-26488 A

### SUMMARY

### Technical Problem

A layout area of a pixel circuit needs to be reduced in order to perform high-resolution display in an organic EL display device. However, when the pixel circuits 91 and 92 are laid out so as to reduce a layout area without a special contrivance, a coupling capacitance Cx is generated between a node N1 to which a gate electrode of the TFT: M1 is connected and the anode electrode of the organic EL element L1.

When the coupling capacitance Cx is generated in the pixel circuit 91, a phenomenon where white display cannot be properly performed in a first few frame periods in which white display needs to be performed may occur in a case where white display is performed after black display. This phenomenon is called a step response. In the pixel circuit 92, an influence of a previous frame can be eliminated and a step response can be prevented by initializing a voltage of the anode electrode of the organic EL element L1 by using the TFT: M7. However, a data voltage needs to be increased by the coupling capacitance Cx in the pixel circuit 92. Thus, when the coupling capacitance Cx is generated in the pixel circuit 92, power consumption of the organic EL display device increases. Further, the gate electrode of the TFT: M7 is connected to a scanning line Gi, and thus a problem also arises that a step response occurs at the time of resetting.

Thus, examples of a problem include providing a display device that can prevent a step response and has low power consumption.

### Solution to Problem

The above-described problem can be solved by a display device. For example, the display device includes: a display portion including a plurality of scanning lines, a plurality of data lines, and a plurality of pixel circuits; a scanning line drive circuit configured to drive the plurality of scanning lines; and a data line drive circuit configured to drive the plurality of data lines, where each of the plurality of pixel circuits includes an electro-optical element provided on a path connecting a first electrical conductive member and a second electrical conductive member and configured to emit light at brightness according to a current flowing through the path, the first electrical conductive member and the second electrical conductive member supplying a power source voltage, and a driving transistor provided in series with the electro-optical element on the path and configured to control an amount of current flowing through the path, wherein a control electrode of the driving transistor is connected to a connection wiring line formed in a wiring line layer closer to a wiring line layer in which a first electrode of the electro-optical element is formed than a wiring line layer in which the control electrode of the driving transistor is formed, and the first electrode of the electro-optical element does not overlap the connection wiring line in a plan view. The above-described problem can also be solved by the pixel circuit included in the above-described display device.

Advantageous Effects of Disclosure

The above-described display device and pixel circuit can reduce a coupling capacitance between a node connected to the control electrode of the driving transistor and the first electrode of the electro-optical element, prevent a step response of the display device, and reduce power consumption of the display device.

### BRIEF DESCRIPTION OF DRAWINGS

FIG. 1 is a block diagram illustrating a configuration of a display device according to a first embodiment.

FIG. 2 is a circuit diagram illustrating a pixel circuit of the display device illustrated in FIG. 1.

FIG. 3 is a timing chart of the display device illustrated in FIG. 1.

FIG. 4 is a layout diagram of the pixel circuit illustrated in FIG. 2.

FIG. 5 is a diagram illustrating a part of FIG. 4 being divided into a plurality of layers.

FIG. 6 is a diagram illustrating a wiring line layer of a node N1 of the pixel circuit illustrated in FIG. 2.

FIG. 7 is a layout diagram of a pixel circuit according to a comparative example.

FIG. 8 is a signal waveform diagram of the display device illustrated in FIG. 1.

FIG. 9 is a layout diagram of a pixel circuit of a display device according to a modification of the first embodiment.

FIG. 10 is a circuit diagram of a pixel circuit of a display device according to a second embodiment.

FIG. 11 is a signal waveform diagram of the display device according to the second embodiment.

FIG. 12 is a circuit diagram of a pixel circuit of a known display device.

FIG. 13 is a circuit diagram of a pixel circuit of a known display device.

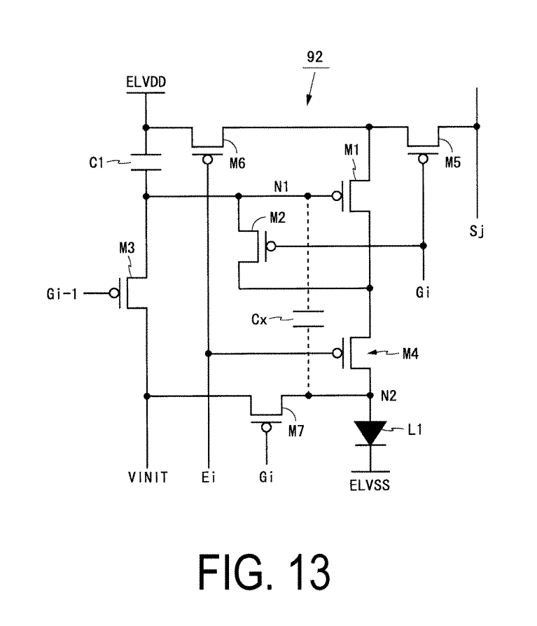

### DESCRIPTION OF EMBODIMENTS

Hereinafter, a display device according to each embodiment will be described with reference to drawings. The display device according to each embodiment is an organic EL display device including a pixel circuit including an organic EL element. The organic EL element is a kind of an electro-optical element, and is also called an organic light emitting diode or an Organic Light Emitting Diode (OLED). In the following description, m and n represent an integer greater than or equal to 2, i represents an integer greater than or equal to 1 and less than or equal to m, and j represents an integer greater than or equal to 1 and less than or equal to n.

The display device according to each embodiment has a characteristic described later in a layout of a pixel circuit. Hereinafter, a display device in which a layout of a pixel circuit has a characteristic described later is referred to as a “display device according to an embodiment”, and a display device in which a layout of a pixel circuit does not have a characteristic described later is referred to as a “known display device”. An overall configuration of the display device according to each embodiment and a basic configuration of the pixel circuit are the same as those of the known display device.

### First Embodiment

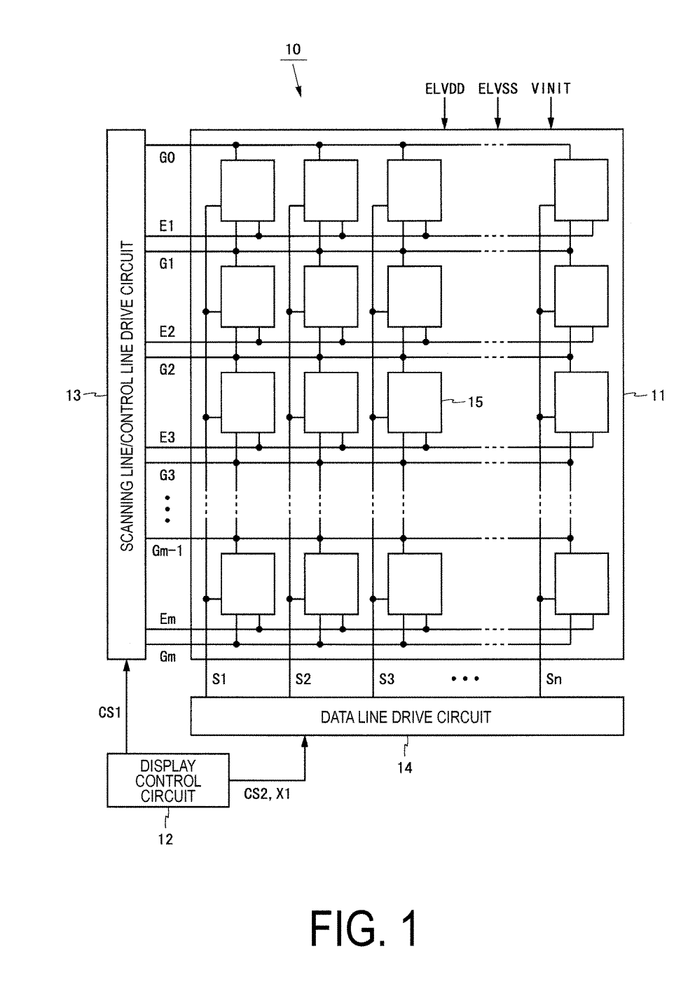

FIG. 1 is a block diagram illustrating a configuration of a display device according to a first embodiment. A display device 10 illustrated in FIG. 1 includes a display portion 11, a display control circuit 12, a scanning line/control line drive circuit 13, and a data line drive circuit 14. The scanning line/control line drive circuit 13 is a circuit combining a scanning line drive circuit that drives a scanning line with a control line drive circuit that drives a control line. When the scanning line/control line drive circuit is described, it represents the scanning line drive circuit and the control line drive circuit.

The display portion 11 includes (m+1) scanning lines G0 to Gm, n data lines S1 to Sn, m control lines E1 to Em, and (m×n) pixel circuits 15. The scanning lines G0 to Gm are arranged parallel to each other. The data lines S1 to Sn are arranged orthogonal to the m scanning lines G1 to Gm and parallel to each other. The scanning lines G1 to Gm and the data lines S1 to Sn intersect at (m×n) locations. The (m×n) pixel circuits 15 are each two-dimensionally arranged corresponding to each intersection point between the scanning lines G1 to Gm and the data lines S1 to Sn. The control lines E1 to Em are arranged parallel to the scanning lines G0 to Gm. Each of the pixel circuits 15 is fixedly supplied with voltages (a high level power source voltage ELVDD, a low level power source voltage ELVSS, and an initialization voltage VINIT) of three kinds by using a wiring line or an electrode (not illustrated). Hereinafter, the high level power source voltage ELVDD is supplied from a high-level power source wiring line, and the low level power source voltage ELVSS is supplied from a common electrode.

The display control circuit 12 outputs a control signal CS1 to the scanning line/control line drive circuit 13, and outputs a control signal CS2 and an image signal X1 to the data line drive circuit 14. The scanning line/control line drive circuit 13 drives the scanning lines G0 to Gm and the control lines E1 to Em on the basis of the control signal CS1. The data line drive circuit 14 drives the data lines S1 to Sn on the basis of the control signal CS2 and the image signal X1.

More specifically, (m+1) line periods from 0-th to m-th line periods are set in one frame period. In the 0-th line period, the scanning line/control line drive circuit 13 applies an on voltage (voltage causing a TFT to turn on. Herein, a low level voltage) to the scanning line G0, and applies an off voltage (voltage causing a TFT to turn off. Herein, a high level voltage) to the scanning lines G1 to Gm. In an i-th line period, the scanning line/control line drive circuit 13 applies an on voltage to an i-th scanning line Gi, and applies an off voltage to remaining m scanning lines. In this way, the pixel circuits 15 in an i-th row are collectively selected in the i-th line period. The data line drive circuit 14 applies n data voltages according to the image signal X1 to the data lines S1 to Sn on the basis of the control signal CS2. In this way, the n data voltages are written to the respective pixel circuits 15 in the i-th row in the i-th line period.

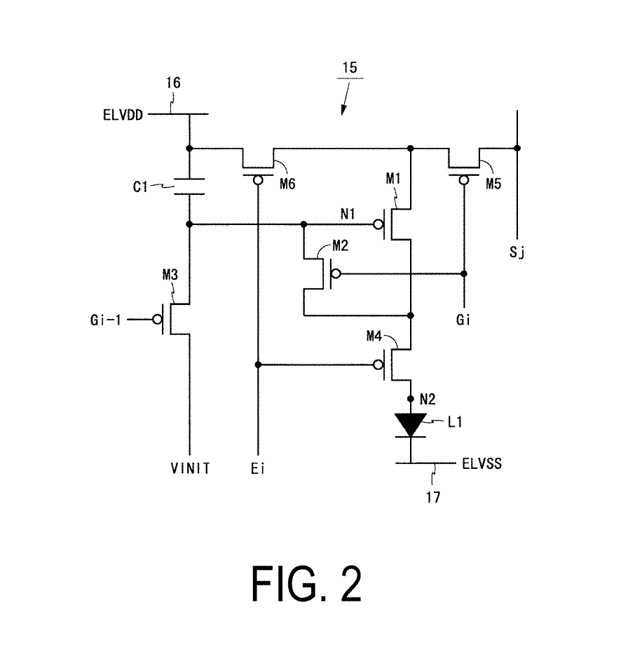

FIG. 2 is a circuit diagram illustrating the pixel circuit 15. FIG. 2 illustrates a pixel circuit 15 in an i-th row and a j-th column. The pixel circuit 15 illustrated in FIG. 2 includes an organic EL element L1, six TFTs: M1 to M6, and a capacitor C1, and is connected to scanning lines Gi and Gi−1, a control line Ei, and a data line Sj. A configuration of such a pixel circuit 15 is called a 6T1C configuration. The TFTs: M1 to M6 are p-channel transistors.

Note that, the TFT included in the pixel circuit 15 may be an amorphous silicon transistor including a channel layer made of amorphous silicon, a low-temperature polysilicon transistor including a channel layer made of low-temperature polysilicon, or an oxide semiconductor transistor including a channel layer formed of an oxide semiconductor. For example, an indium-gallium-zinc oxide (referred to as IGZO) may be used as an oxide semiconductor.

A source electrode of the TFT: M6 and one electrode (an upper electrode in FIG. 2) of the capacitor C1 are connected to a high-level power source wiring line 16 that supplies the high level power source voltage ELVDD. A first conduction electrode (a right electrode in FIG. 2) of the TFT: M5 is connected to the data line Sj. A drain electrode of the TFT: M6 and a second conduction electrode of the TFT: M5 are connected to a source electrode of the TFT: M1. A drain electrode of the TFT: M1 is connected to a first conduction electrode (a lower electrode in FIG. 2) of the TFT: M2 and a source electrode of the TFT: M4. A drain electrode of the TFT: M4 is connected to an anode electrode of the organic EL element L1. A cathode electrode of the organic EL element L1 is connected to a common electrode 17 that supplies the low level power source voltage ELVSS. A gate electrode of the TFT: M1 is connected to a second conduction electrode of the TFT: M2, the other electrode of the capacitor C1, and a first conduction electrode (an upper electrode in FIG. 2) of the TFT: M3. The initialization voltage VINIT is applied to a second conduction electrode of the TFT: M3. Gate electrodes of the TFTs: M2 and M5 are connected to the scanning line Gi. Gate electrodes of the TFTs: M4 and M6 are connected to the control line Ei. A gate electrode of the TFT: M3 together with gate electrodes of TFTs: M2 and M5 included in a pixel circuit 15 in an adjacent row are connected to the scanning line Gi−1. Hereinafter, a node to which the gate electrode of the TFT: M1 is connected is referred to as N1, and a node to which the anode electrode of the organic EL element L1 is connected is referred to as N2.

The organic EL element L1 functions as an electro-optical element that is provided on a path connecting a first electrical conductive member (the high-level power source wiring line 16) and a second electrical conductive member (the common electrode 17) supplying a power source voltage, and emits light at brightness according to a current flowing through the path. The TFT: M1 functions as a driving transistor that is provided in series with the electro-optical element on the path, and controls the amount of current flowing through the path. The TFT: M5 functions as a writing control transistor including the first conduction electrode connected to the data line Sj, including the second conduction electrode connected to a first conduction electrode of the driving transistor (the source electrode of the TFT: M1), and including a control electrode connected to the scanning line Gi. The TFT: M2 functions as a threshold value compensation transistor including the first conduction electrode connected to a second conduction electrode of the driving transistor (the drain electrode of the TFT: M1), including the second conduction electrode connected to a control electrode of the driving transistor (the gate electrode of the TFT: M1), and including a control electrode connected to the scanning line Gi. The TFT: M6 functions as a first light emission control transistor including a first conduction electrode connected to the first electrical conductive member (the high-level power source wiring line 16), including a second conduction electrode connected to the first conduction electrode of the driving transistor, and including a control electrode connected to the control line Ei. The TFT: M4 functions as a second light emission control transistor including a first conduction electrode connected to the second conduction electrode of the driving transistor, including a second conduction electrode connected to a first electrode of the electro-optical element (the anode electrode of the organic EL element L1), and including a control electrode connected to the control line Ei. The capacitor C1 is provided between the first electrical conductive member and the control electrode of the driving transistor. A second electrode of the electro-optical element (the cathode electrode of the organic EL element L1) is connected to the second electrical conductive member (the common electrode 17). The TFT: M3 functions as an initialization transistor including the first conduction electrode connected to the control electrode of the driving transistor, and including the second conduction electrode to which the initialization voltage VINIT is applied. A control electrode of the initialization transistor is connected to the scanning line Gi−1 of a pixel circuit in an adjacent row.

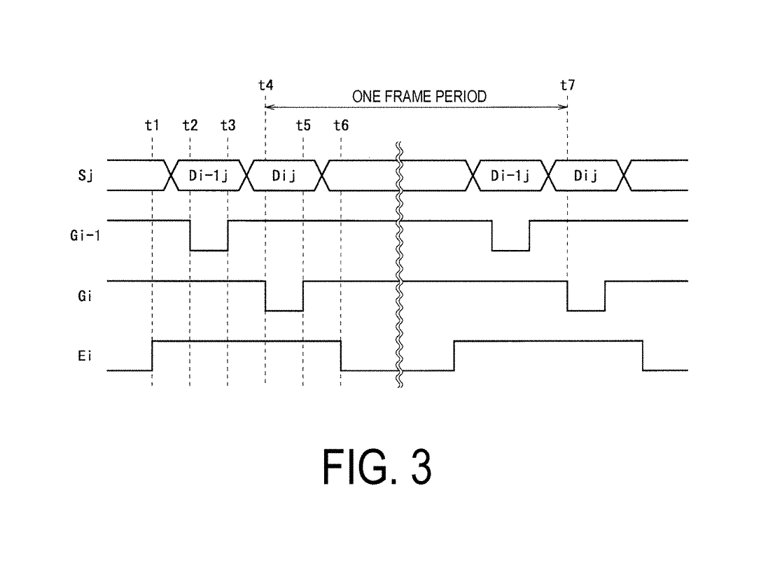

FIG. 3 is a timing chart of the display device 10. FIG. 3 illustrates a change in input signal when a data voltage is written to a pixel circuit 15 in an i-th row and a j-th column. In FIG. 3, a period from a time t4 to a time t7 corresponds to one frame period. Hereinafter, signals on the scanning lines Gi and Gi−1 are respectively referred to as scanning signals Gi and Gi−1, and a signal on the control line Ei is referred to as a control signal Ei.

The scanning signals Gi and Gi−1 are at a high level and the control signal Ei is at a low level before a time t1. Thus, the TFTs: M4 and M6 are in an on state, and the TFTs: M2, M3, and M5 are in an off state. At this time, when a gate-source voltage of the TFT: M1 is less than or equal to a threshold voltage, a current flows from the high-level power source wiring line 16 toward the common electrode 17 via the TFTs: M6, M1, and M4 and the organic EL element L1, and the organic EL element L1 emits light at brightness according to the amount of the flowing current.

The control signal Ei is changed to the high level at the time t1. Accordingly, the TFTs: M4 and M6 turn off. Thus, no current flows via the organic EL element L1 at and after the time t1, and the organic EL element L1 is brought into a non-emitting state.

Next, the scanning signal Gi−1 is changed to the low level at a time t2. Accordingly, the TFT: M3 turns on. Thus, a gate voltage of the TFT: M1 is initialized to the initialization voltage VINIT. The initialization voltage VINIT is set at a low level such that the TFT: M1 turns on immediately after the scanning signal Gi is changed to the low level.

Next, the scanning signal Gi−1 is changed to the high level at a time t3. Accordingly, the TFT: M3 turns off. Thus, the initialization voltage VINIT is not applied to the gate electrode of the TFT: M1 at and after the time t3.

Next, the scanning signal Gi is changed to the low level at the time t4. Accordingly, the TFTs: M2 and M5 turn on. The gate electrode and the drain electrode of the TFT: M1 are electrically connected to each other via the TFT: M2 in an on state at and after the time t4, and thus the TFT: M1 is in a diode-connected state. Thus, a current flows from the data line Sj toward the gate electrode of the TFT: M1 via the TFTs: M5, M1, and M2. The gate voltage of the TFT: M1 rises due to this current. When a gate-source voltage of the TFT: M1 is equal to a threshold voltage of the TFT: M1, no current flows. Given that a threshold voltage of the TFT: M1 is Vth and a voltage of the data line Sj in a period from the time t4 to a time t5 is Vd, a gate voltage of the TFT: M1 after a lapse of sufficient time from the time t4 is (Vd−|Vth|).

Next, the scanning signal Gi is changed to the high level at the time t5. Accordingly, the TFTs: M2 and M5 turn off. At and after the time t5, the capacitor C1 holds an inter-electrode voltage (ELVDD−Vd+|Vth|).

Next, the control signal Ei is changed to the low level at a time t6. Accordingly, the TFTs: M4 and M6 turn on. At and after the time t6, a current flows from the high-level power source wiring line 16 toward the common electrode 17 via the TFTs: M6, M1, and M4 and the organic EL element L1. A gate-source voltage Vgs of the TFT: M1 is held at (ELVDD−Vd+|Vth|) by action of the capacitor C1. Therefore, a current I1 flowing at and after the time t6 is given by a next expression (1) by using a constant K.

$$\begin{matrix}I 1 = {K ( Vgs - \vert Vth \vert )}^{2} \\ = {K ( ELVDD - Vd )}^{2}\end{matrix} \qquad ( 1 )$$

In this way, the organic EL element L1 emits light at brightness according to the data voltage Vd written to the pixel circuit 15 at and after the time t6 regardless of the threshold voltage Vth of the TFT: M1.

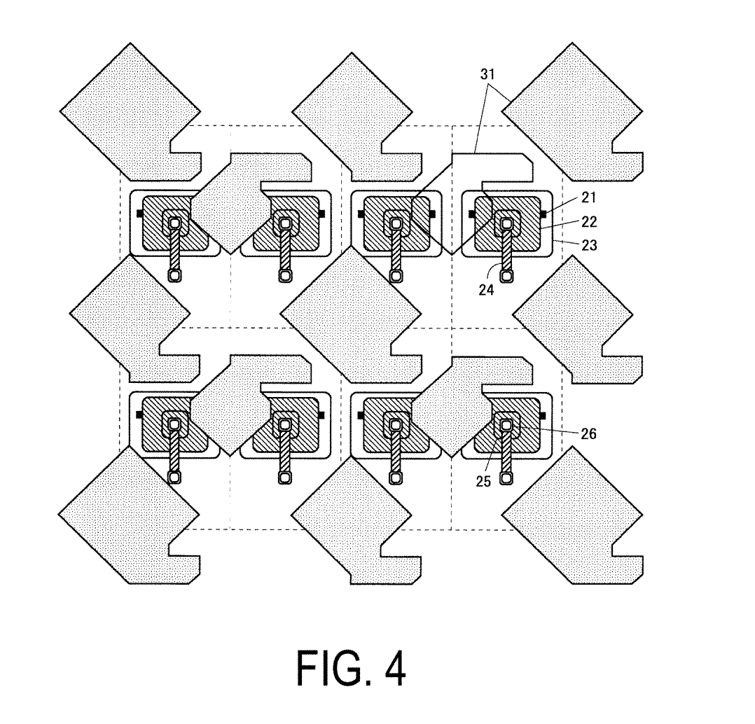

FIG. 4 is a layout diagram of the pixel circuit 15. FIG. 4 illustrates a layout near the gate electrode of the TFT: M1 and a layout of an anode electrode 31 of the organic EL element L1. Note that, both of the layout diagrams do not illustrate the layouts faithfully, and illustrate abstract layouts to a degree that a characteristic of the layout is understandable. Further, a region surrounded by a broken line corresponds to one subpixel.

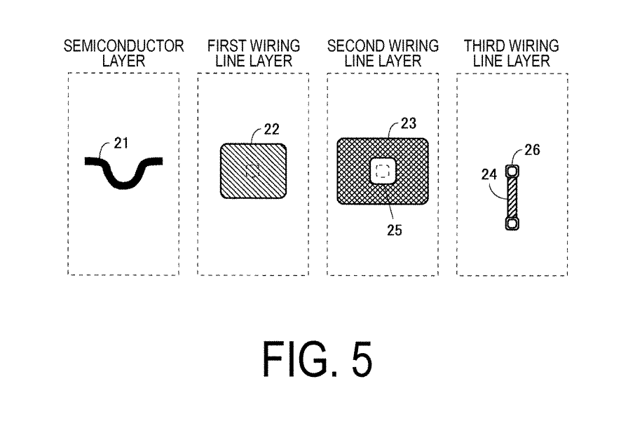

FIG. 5 is a diagram illustrating a layout near the gate electrode of the TFT: M1 being divided into a plurality of layers. The pixel circuit 15 is formed by forming a semiconductor layer, first to third wiring line layers, an anode electrode layer, and the like on a substrate in order. The first to third wiring line layers are metal wiring line layers. As illustrated in FIG. 5, a semiconductor portion 21, a gate electrode 22, a capacitance wiring line 23, and a connection wiring line 24 are formed in the semiconductor layer and the first to third wiring line layers, respectively. The semiconductor portion 21 functions as a channel region of the TFT: M1. The gate electrode 22 is the gate electrode of the TFT: M1, and is formed to cover the semiconductor portion 21. The capacitance wiring line 23 is a wiring line for forming a capacitance in a pixel circuit, and is disposed to overlap the gate electrode 22 in a plan view. The high level power source voltage VDD is applied to the capacitance wiring line 23, and the capacitance wiring line 23 also functions as the high-level power source wiring line 16. The gate electrode 22 and the capacitance wiring line 23 are disposed to face each other, and thus the capacitor C1 illustrated in FIG. 2 is formed. The gate electrode 22 also functions as the other electrode (a lower electrode in FIG. 2) of the capacitor C1.

In this way, in the display device, the gate electrode 22 of the TFT: M1 is formed in the first wiring line layer, the capacitance wiring line 23 is formed in the second wiring line layer in a layer above the first wiring line layer, the connection wiring line 24 is formed in the third wiring line layer in a layer above the second wiring line layer, and the anode electrode 31 of the organic EL element L1 is formed in a layer above the third wiring line layer.

A first inorganic insulating film is provided between the semiconductor layer and the first wiring line layer. A second inorganic insulating film is provided between the first wiring line layer and the second wiring line layer. A third inorganic insulating film is provided between the second wiring line layer and the third wiring line layer. A flattering film is provided between the third wiring line layer and the anode electrode layer. The flattering film is formed by using a resin such as an acrylic resin, a polyimide resin, and an epoxy resin, for example.

The other conduction electrode of the TFT: M2 and one conduction electrode of the TFT: M3 in addition to the gate electrode of the TFT: M1 and the other electrode of the capacitor C1 are connected to the node N1 illustrated in FIG. 2. The connection wiring line 24 is formed for electrically connecting the other conduction electrode of the TFT: M2 and one conduction electrode of the TFT: M3 to the gate electrode 22. To electrically connect the gate electrode 22 formed in the first wiring line layer to the connection wiring line 24 formed in the third wiring line layer, an opening 25 is formed in the second inorganic insulating film, the capacitance wiring line 23 formed in the second wiring line layer, and the third inorganic insulating film, and a contact hole 26 connecting the first wiring line layer to the third wiring line layer is formed in the opening 25. The gate electrode 22 and the connection wiring line 24 are electrically connected to each other through the contact hole 26.

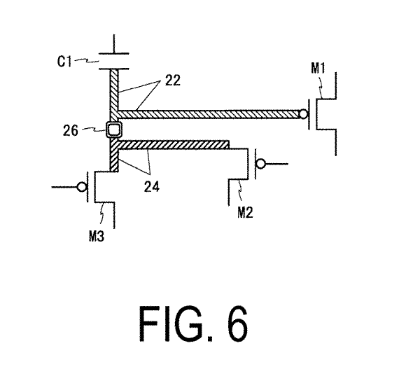

FIG. 6 is a diagram illustrating a wiring line layer of the node N1. As illustrated in FIG. 6, the gate electrode of the TFT: M1 and the other electrode of the capacitor C1 are electrically connected to each other with the gate electrode 22 formed in the first wiring line layer. The other conduction electrode of the TFT: M2 and one conduction electrode of the TFT: M3 are electrically connected to the gate electrode 22 through the connection wiring line 24 formed in the third wiring line layer and the contact hole 26 connecting the first wiring line layer to the third wiring line layer.

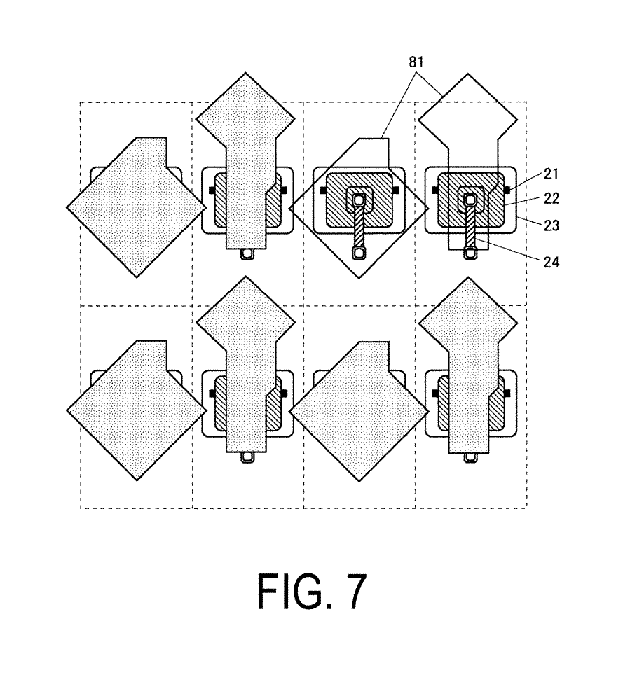

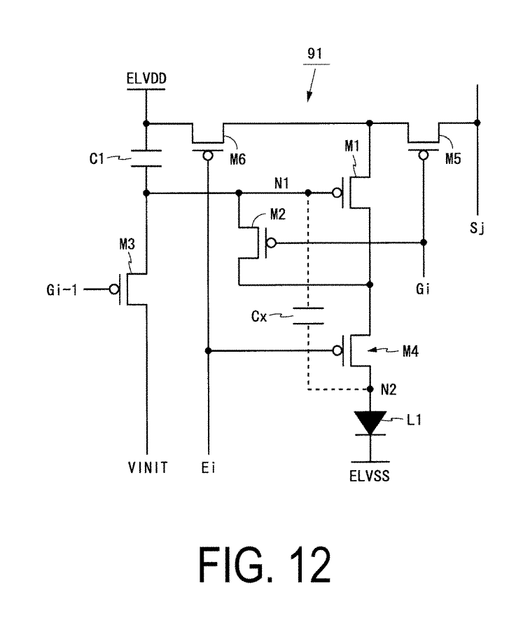

FIG. 7 is a layout diagram of a pixel circuit according to a comparative example. FIG. 7 illustrates a layout of the pixel circuit 91 in the related art illustrated in FIG. 12. FIG. 7 illustrates a layout near the gate electrode of the TFT: M1 and a layout of an anode electrode 81 of the organic EL element L1, similarly to FIG. 4.

As illustrated in FIGS. 4 and 7, the pixel circuit 15 according to the present embodiment is different from the pixel circuit 91 in the related art in the layout of the anode electrode of the organic EL element L1. In the pixel circuit 91 in the related art (FIG. 7), the anode electrode 81 of the organic EL element L1 is laid out so as to allow the gate electrode 22 and the connection wiring line 24 to overlap the anode electrode 81 in a plan view. As a result, the anode electrode 81 overlaps the entire connection wiring line 24 in the plan view, and overlaps more than or equal to a half of the gate electrode 22 in the plan view. Thus, the coupling capacitance Cx is generated between the node N1 and the anode electrode of the organic EL element L1 in the pixel circuit 91 in the related art.

On the other hand, in the pixel circuit 15 according to the present embodiment (FIG. 5), the anode electrode 31 of the organic EL element L1 is laid out so as not to overlap the gate electrode 22 and the connection wiring line 24 in a plan view as much as possible. As a result, the anode electrode 31 does not overlap the connection wiring line 24 and the contact hole 26 in the plan view, and overlaps less than or equal to about ¼ of the gate electrode 22 in the plan view. Further, the anode electrode 31 is disposed to avoid the opening 25, and does not overlap the opening 25 in the plan view. Thus, a coupling capacitance between the node N1 and the anode electrode of the organic EL element L1 is small to a negligible degree in the pixel circuit 15 according to the present embodiment.

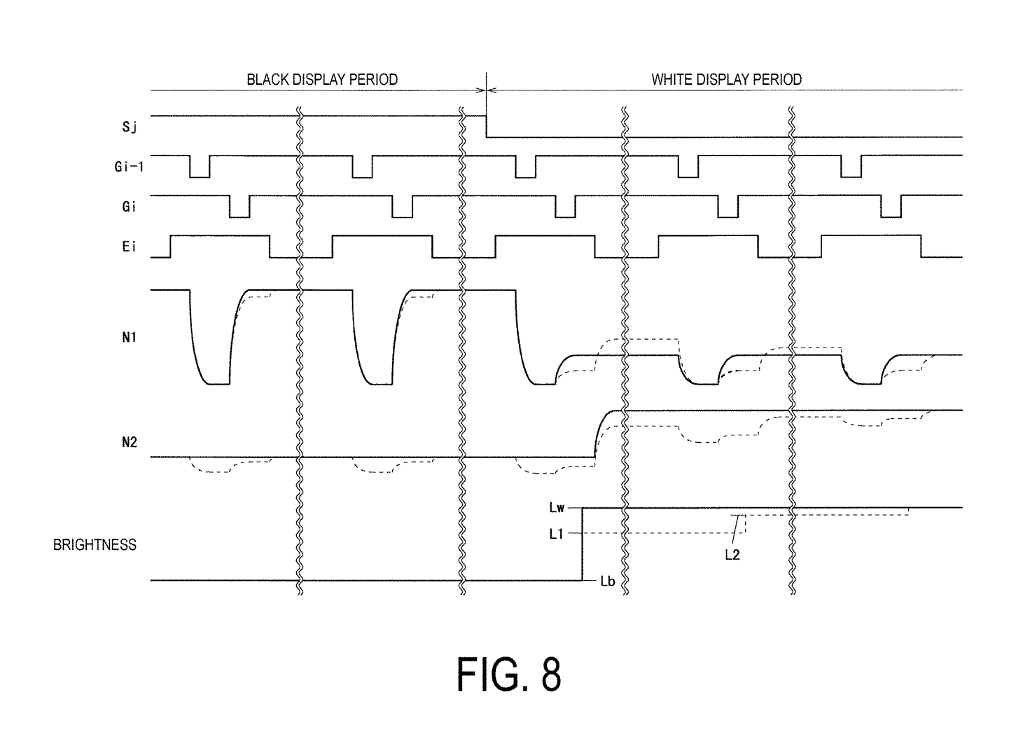

FIG. 8 is a signal waveform diagram of the display device 10. FIG. 8 illustrates, by solid lines, a change in input signal of the pixel circuit 15, a change in voltage of the nodes N1 and N2, and a change in brightness of the organic EL element 1 when white display is performed after black display. FIG. 8 illustrates the same contents of the pixel circuit 91 in the related art by broken lines. Hereinafter, effects of the display device 10 according to the present embodiment will be described in comparison with the known display device.

When white display is performed after black display in the known display device, writing of a data voltage is completed and the control line Ei is changed to the low level, and then a current passing through the TFTs: M5, M4, and M1 and the organic EL element L1 flows, and a voltage of the anode electrode of the organic EL element L1 rises. In the pixel circuit 91 in the related art, the coupling capacitance Cx is located between the node N1 and the anode electrode of the organic EL element L1. Thus, when a voltage of the anode electrode of the organic EL element L1 rises, a voltage of the gate electrode of the TFT: M1 also rises. Therefore, a smaller amount of current flowing through the TFT: T1 than a predetermined amount is defined, and brightness of the organic EL element L1 does not rise to a desired level (white level). As a result, white display cannot be properly performed in a frame period in which white display needs to be performed first.

A fluctuation amount of voltage of the anode electrode of the organic EL element L1 gradually decreases in a subsequent frame period. Thus, brightness of the organic EL element L1 rises to a white level after a few frame periods, and white display can be properly performed. In this way, in the known display device, white display cannot be properly performed in a first few frame periods in which white display needs to be performed when white display is performed after black display (step response). Given that brightness of the organic EL element L1 during black display is Lb, and brightness of the organic EL element L1 during white display is Lw. As indicated by the broken lines in FIG. 8, brightness of the organic EL element L1 included in the known display device is first changed from Lb to L1, then changed from L1 to L2, and changed from L2 to Lw next (Lb<L1<L2<Lw).

When white display is performed after black display in the display device 10 according to the present embodiment, writing of a data voltage is completed and the control line Ei is changed to the low level, and then a voltage of the anode electrode of the organic EL element L1 rises, similarly to the known display device. In the pixel circuit 15 according to the present embodiment, a coupling capacitance between the node N1 and the anode electrode of the organic EL element L1 is small to a negligible degree. Thus, even when a voltage of the anode electrode of the organic EL element L1 rises, a voltage of the gate electrode of the TFT: M1 hardly rises. Therefore, a current flowing through the TFT: T1 immediately reaches a predetermined amount, and brightness of the organic EL element L1 rises to a desired level (white level). Therefore, white display can be properly performed in a frame period in which white display needs to be performed first.

Further, a data voltage needs to be increased by the coupling capacitance Cx in the pixel circuit 91 in the related art, and thus power consumption of the display device increases. On the other hand, a data voltage does not need to be increased by the coupling capacitance Cx in the display device 10 according to the present embodiment, and thus an increase in power consumption can be prevented.

As described above, in the display device 10 according to the present embodiment, the connection wiring line 24 formed in the wiring line layer (third wiring line layer) closer to the wiring line layer (anode electrode layer) in which the first electrode of the electro-optical element (anode electrode of the organic EL element L1) is formed than the wiring line layer (first wiring line layer) in which the control electrode of the driving transistor is formed is connected to the control electrode of the driving transistor (the gate electrode of the TFT: M1), and the first electrode of the electro-optical element is disposed so as not to overlap the connection wiring line in a plan view. Therefore, the display device 10 according to the present embodiment reduces a coupling capacitance between the node N1 connected to the control electrode of the driving transistor and the first electrode of the electro-optical element, and thus can prevent a step response of the display device and reduce power consumption of the display device.

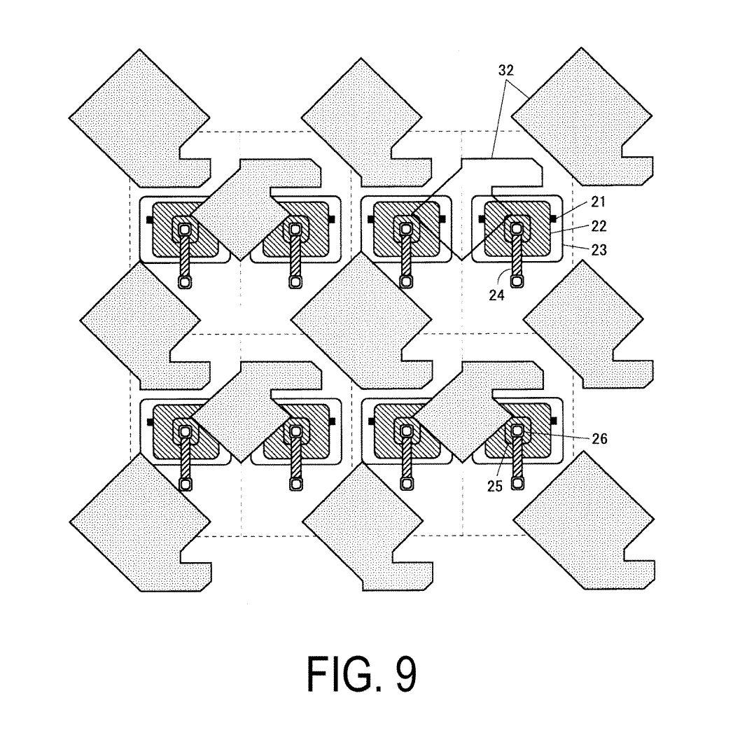

The following modification can be made on the display device according to the present embodiment. FIG. 9 is a layout diagram of a pixel circuit of a display device according to a modification of the present embodiment. Also in FIG. 9, an anode electrode 32 of an organic EL element L1 is laid out so as not to overlap a connection wiring line 24 in a plan view, similarly to FIG. 4. Further, the anode electrode 32 is laid out without avoiding an opening 25 formed in a capacitance wiring line 23. As a result, the anode electrode 32 slightly overlaps the opening 25.

A first wiring line layer is farther from an anode electrode layer than a third wiring line layer. Thus, a coupling capacitance when the anode electrode 32 overlaps a gate electrode 22 in a plan view is sufficiently smaller than a coupling capacitance when the anode electrode 32 overlaps the connection wiring line 24 in the plan view. Therefore, although the anode electrode 32 slightly overlaps the opening 25, a coupling capacitance between a node N1 and the anode electrode 32 of the organic EL element L1 is sufficiently small as long as the anode electrode 32 does not overlap the connection wiring line 24 formed in the third wiring line layer in the plan view. Therefore, even the display device according to the modification can obtain the effects similar to those of the display device 10 according to the first embodiment.

### Second Embodiment

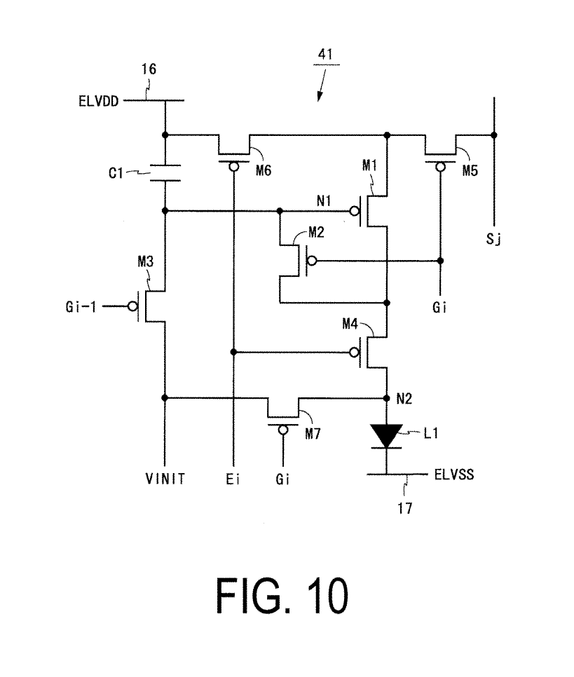

A display device according to a second embodiment has the same configuration (FIG. 1) as that of the display device according to the first embodiment. However, the display device according to the present embodiment includes a pixel circuit 41 illustrated in FIG. 10 instead of the pixel circuit 15 illustrated in FIG. 2. The same elements in the present embodiment as those in the first embodiment are denoted by the same reference signs, and description thereof will be omitted.

FIG. 10 illustrates a pixel circuit 41 in an i-th row and a j-th column. The pixel circuit 41 illustrated in FIG. 10 includes an organic EL element L1, seven TFTs: M1 to M7, and a capacitor C1, and is connected to scanning lines Gi and Gi−1, a control line Ei, and a data line Sj. A configuration of such a pixel circuit 41 is called a 7T1C configuration. The TFTs: M1 to M7 are p-channel transistors.

The pixel circuit 41 includes the TFT: M7 added to the pixel circuit 15 according to the first embodiment. One conduction electrode of the TFT: M7 (a right electrode in FIG. 10) is connected to an anode electrode of the organic EL element L1. The initialization voltage VINIT is applied to the other conduction electrode of the TFT: M7. A gate electrode of the TFT: M7 is connected to the scanning line Gi. The TFT: M7 functions as a second initialization transistor including a first conduction electrode connected to a first electrode of an electro-optical element, and including a second conduction electrode to which the initialization voltage VINIT is applied. A control electrode of the second initialization transistor is connected to the scanning line Gi.

Similarly to the pixel circuit 15 according to the first embodiment, also in the pixel circuit 41 according to the present embodiment, the anode electrode of the organic EL element L1 is laid out so as not to overlap a connection wiring line connected to a gate electrode of the TFT: M1 in a plan view. The anode electrode of the organic EL element L1 is preferably disposed so as not to overlap an opening formed in a capacitance wiring line in a plan view. The anode electrode of the organic EL element L1 may be disposed to slightly overlap the opening formed in the capacitance wiring line.

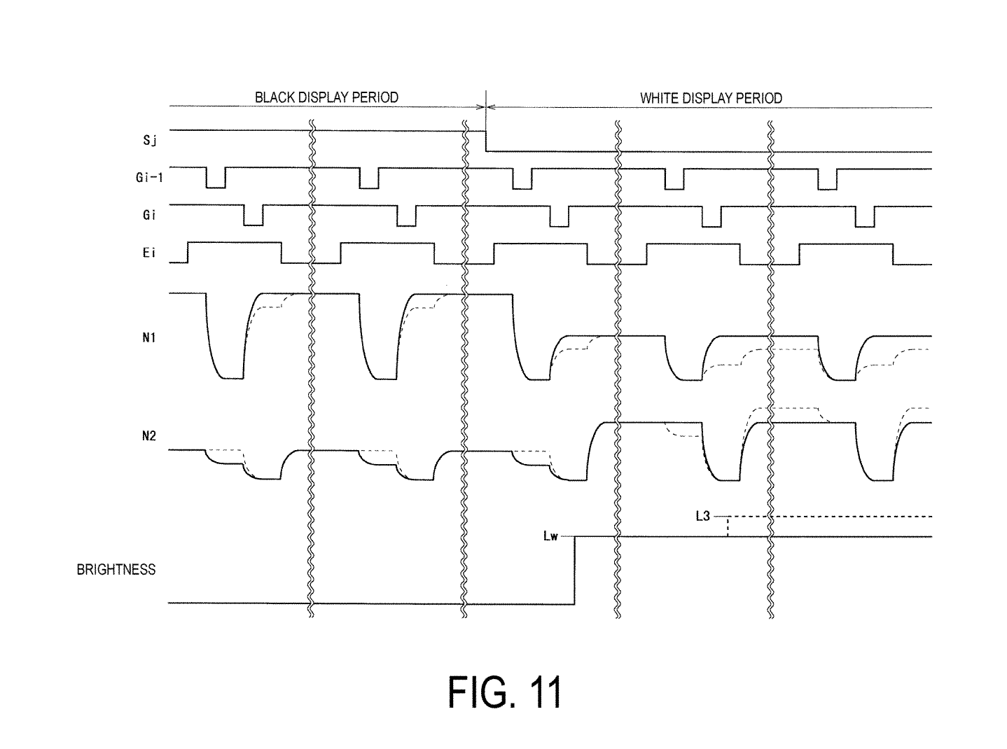

FIG. 11 is a signal waveform diagram of the display device according to the present embodiment. FIG. 11 illustrates the same contents as those in FIG. 8 when white display is performed after black display. In the known display device, when the scanning signal Gi is at a high level, the TFTs: M2, M5, and M7 turn on, and a compensation operation and resetting of a voltage of the anode electrode of the organic EL element L1 are performed simultaneously. In the pixel circuit 92 in the related art, the coupling capacitance Cx is located between the node N1 and the anode electrode of the organic EL element L1. Thus, when a voltage of the anode electrode of the organic EL element L1 changes, a voltage of the gate electrode of the TFT: M1 also changes. When white display is performed after black display, a change in voltage of the anode electrode of the organic EL element L1 at the time of resetting is small. At this time, a change in gate voltage of the TFT: M1 is also small, and thus the gate voltage of the TFT: M1 can be properly controlled to a desired level.

Subsequently, when white display is performed after white display, a change in voltage of the anode electrode of the organic EL element L1 at the time of resetting is great. At this time, a change in gate voltage of the TFT: M1 is also great, and thus the gate voltage of the TFT: M1 cannot be properly controlled to a desired level. When the gate voltage of the TFT: M1 decreases, a current flowing through the organic EL element L1 increases and brightness of the organic EL element L1 becomes higher than a desired level (white level). As indicated by broken lines in FIG. 11, brightness of the organic EL element L1 included in the known display device is first changed from Lb to Lw, and then changed from Lw to L3 (Lb<Lw<L3). In a subsequent frame period, a voltage of the anode electrode of the organic EL element L1 is initialized to the initialization voltage VINIT in each frame period, and thus the gate voltage of the TFT: M1 always decreases by the same amount. Thus, brightness of the organic EL element L1 in each frame period is almost fixed. In this way, a step response occurs at the time of resetting in the known display device.

Also in the display device according to the present embodiment, when the scanning signal Gi is at a high level, the TFTs: M2, M5, and M7 turn on, and a compensation operation and resetting of a voltage of the anode electrode of the organic EL element L1 are performed simultaneously, similarly to the known display device. In the pixel circuit 41 according to the present embodiment, a coupling capacitance between the node N1 and the anode electrode of the organic EL element L1 is small to a negligible degree. Thus, even when a voltage of the anode electrode of the organic EL element L1 changes, a voltage of the gate electrode of the TFT: M1 hardly changes. Therefore, also when white display is performed after white display, the gate voltage of the TFT: M1 can be properly controlled to a desired level, and brightness of the organic EL element L1 can be controlled to a desired level (white level).

Further, similarly to the display device 10 according to the first embodiment, a data voltage does not need to be increased by the coupling capacitance Cx in the display device according to the present embodiment, and thus an increase in power consumption can be prevented.

As described above, the display device according to the present embodiment can reduce a coupling capacitance between the node connected to the control electrode of the driving transistor and the first electrode of the electro-optical element, prevent a step response of the display device, and reduce power consumption of the display device.

The following modifications can be made on the display device according to each of the embodiments described above. For example, the pixel circuits 15 and 41 are laid out in a specific manner in the first and second embodiments, respectively, but the pixel circuits 15 and 41 may be laid out in the other manner. For example, at least one of a plurality of first electrodes (anode electrodes of organic EL elements L1) included in a plurality of pixel circuits may be disposed to overlap a capacitance wiring line including an opening in a plan view (first modification). A plurality of capacitance wiring lines including openings may be formed in parallel to each other, and at least one of a plurality of first electrodes included in a plurality of pixel circuits may be disposed so as to overlap both of two capacitance wiring lines located close to each other in a plan view (second modification). At least one of a plurality of first electrodes included in a plurality of pixel circuits may be disposed to overlap a control electrode of a driving transistor in a plan view (third modification). A control electrode (gate electrode) of a driving transistor may be formed two-dimensionally, and at least one of a plurality of first electrodes included in a plurality of pixel circuits may be disposed to overlap all control electrodes of four driving transistors located close to each other in a plan view. In the display device according to the modification, a pixel circuit may be formed in a plurality of wiring line layers including four or more metal wiring line layers.

The display device including the pixel circuit having the specific configuration is described in the first and second embodiments, but a display device including the other pixel circuit that includes an organic EL element and a driving transistor and has a layout having the above-described characteristic may be configured. For example, a display device including a pixel circuit in which the TFT: M3 is omitted from the pixel circuit 15 may be configured. Further, a display portion may not include a plurality of control lines in the display device according to the modification. In this case, a control line drive circuit does not need to be provided in the display device according to the modification.

The organic EL display device including the pixel circuit including the organic EL element (organic light emitting diode) is described as an example of a display device including a pixel circuit including an electro-optical element in the first and second embodiments, but an inorganic EL display device including a pixel circuit including an inorganic light emitting diode and a quantum dot light emitting diode (QLED) display device including a pixel circuit including a QLED may be configured by a similar method.

### REFERENCE SIGNS LIST

10 Display device
11 Display portion
12 Display control circuit
13 Scanning line/control line drive circuit
14 Data line drive circuit
15, 41 Pixel circuit
16 High-level power source wiring line (first electrical conductive member)
17 Common electrode (second electrical conductive member)
21 Semiconductor portion
22 Gate electrode (control electrode)
23 Capacitance wiring line
24 Connection wiring line
25 Opening
26 Contact hole
31, 32 Anode electrode (first electrode)
L1 Organic EL element (electro-optical element)
M1 TFT (driving transistor)
M2 TFT (threshold value compensation transistor)
M3 TFT (initialization transistor)
M4 TFT (second light emission control transistor)
M5 TFT (writing control transistor)
M6 TFT (first light emission control transistor)
M7 TFT (second initialization transistor)

1. A display device comprising:
a display portion including a plurality of scanning lines, a plurality of data lines, and a plurality of pixel circuits;
a scanning line drive circuit configured to drive the plurality of scanning lines; and
a data line drive circuit configured to drive the plurality of data lines,
wherein each of the plurality of pixel circuits includes
an electro-optical element provided on a path connecting a first electrical conductive member and a second electrical conductive member and configured to emit light at brightness according to a current flowing through the path, the first electrical conductive member and the second electrical conductive member supplying a power source voltage, and
a driving transistor provided in series with the electro-optical element on the path and configured to control an amount of current flowing through the path, wherein a control electrode of the driving transistor is connected to a connection wiring line formed in a wiring line layer closer to a wiring line layer in which a first electrode of the electro-optical element is formed than a wiring line layer in which the control electrode of the driving transistor is formed,
the first electrode of the electro-optical element does not overlap the connection wiring line in a plan view,
the display portion further includes a plurality of control lines,
the display device further includes a control line drive circuit configured to drive the plurality of control lines,
each of the plurality of pixel circuits further includes
a writing control transistor including a first conduction electrode connected to a data line of the plurality of data lines, a second conduction electrode connected to a first conduction electrode of the driving transistor, and a control electrode connected to a scanning line of the plurality of scanning lines,
a threshold value compensation transistor including a first conduction electrode connected to a second conduction electrode of the driving transistor, a second conduction electrode connected to the control electrode of the driving transistor, and a control electrode connected to the scanning line,
a first light emission control transistor including a first conduction electrode connected to the first electrical conductive member, a second conduction electrode connected to the first conduction electrode of the driving transistor, and a control electrode connected to a control line of the plurality of control lines,
a second light emission control transistor including a first conduction electrode connected to the second conduction electrode of the driving transistor, a second conduction electrode connected to the first electrode of the electro-optical element, and a control electrode connected to the control line, and
a capacitor provided between the first electrical conductive member and the control electrode of the driving transistor, and
a second electrode of the electro-optical element is connected to the second electrical conductive member.

2. The display device according to claim 1,
wherein each of the plurality of pixel circuits further includes a capacitance wiring line formed in a wiring line layer between the wiring line layer in which the control electrode of the driving transistor is formed and the wiring line layer in which the connection wiring line is formed,
the capacitance wiring line overlaps the control electrode of the driving transistor in a plan view and includes an opening in a part of a position overlapping the control electrode of the driving transistor, and
the control electrode of the driving transistor and the connection wiring line are connected to each other through a contact hole formed in the opening.

3. The display device according to claim 2,
wherein the first electrode of the electro-optical element does not overlap the opening in a plan view.

4. The display device according to claim 2,
wherein at least one of a plurality of the first electrodes included in the plurality of pixel circuits overlaps the capacitance wiring line including the opening in a plan view.

5. The display device according to claim 2,
wherein a plurality of the capacitance wiring lines each including the opening are formed in parallel to each other, and
at least one of a plurality of the first electrodes included in the plurality of pixel circuits overlaps both of two capacitance wiring lines located close to each other in a plan view.

6. The display device according to claim 2,
wherein at least one of a plurality of the first electrodes included in the plurality of pixel circuits overlaps the control electrode of the driving transistor in a plan view.

7. The display device according to claim 2,
wherein the control electrode of the driving transistor is formed two-dimensionally, and
at least one of a plurality of the first electrodes included in the plurality of pixel circuits overlaps all control electrodes of two driving transistors located close to each other in a plan view.

8. The display device according to claim 2,
wherein the control electrode of the driving transistor is formed in a first wiring line layer,
the capacitance wiring line is formed in a second wiring line layer in a layer above the first wiring line layer,
the connection wiring line is formed in a third wiring line layer in a layer above the second wiring line layer, and
the first electrode of the electro-optical element is formed in a layer above the third wiring line layer.

9. (canceled)

10. The display device according to claim 1,
wherein each of the plurality of pixel circuits further includes an initialization transistor including a first conduction electrode connected to the control electrode of the driving transistor and a second conduction electrode to which an initialization voltage is applied.

11. The display device according to claim 10,
wherein a control electrode of the initialization transistor is connected to a scanning line of a pixel circuit in an adjacent row.

12. The display device according to claim 10,
wherein each of the plurality of pixel circuits further includes a second initialization transistor including a first conduction electrode connected to the first electrode of the electro-optical element and a second conduction electrode to which the initialization voltage is applied.

13. The display device according to claim 12,
wherein a control electrode of the second initialization transistor is connected to the scanning line.

14-19. (canceled)

20. A display device comprising:
a display portion including a plurality of scanning lines, a plurality of data lines, and a plurality of pixel circuits;
a scanning line drive circuit configured to drive the plurality of scanning lines; and
a data line drive circuit configured to drive the plurality of data lines,
wherein each of the plurality of pixel circuits includes
an electro-optical element provided on a path connecting a first electrical conductive member and a second electrical conductive member and configured to emit light at brightness according to a current flowing through the path, the first electrical conductive member and the second electrical conductive member supplying a power source voltage, and
a driving transistor provided in series with the electro-optical element on the path and configured to control an amount of current flowing through the path, wherein a control delectrode of the driving transistor is connected to a connection wiring line formed in a wiring line layer closer to a wiring line layer in which a first electrode of the electro-optical element is formed than a wiring line layer in which the control electrode of the driving transistor is formed,
the first electrode of the electro-optical element does not overlap the connection wiring line in a plan view,
each of the plurality of pixel circuits further includes a capacitance wiring line formed in a wiring line layer between the wiring line layer in which the control electrode of the driving transistor is formed and the wiring line layer in which the connection wiring line is formed,
the capacitance wiring line overlaps the control electrode of the driving transistor in a plan view and includes an opening in a part of a position overlapping the control electrode of the driving transistor,
the control electrode of the driving transistor and the connection wiring line are connected to each other through a contact hole formed in the opening,
the control electrode of the driving transistor is formed in a first wiring line layer,
the capacitance wiring line is formed in a second wiring line layer in a layer above the first wiring line layer,
the connection wiring line is formed in a third wiring line layer in a layer above the second wiring line layer, and
the first electrode of the electro-optical element is formed in a layer above the third wiring line layer.

21. The display device according to claim 20,
wherein the first electrode of the electro-optical element does not overlap the opening in a plan view.

22. The display device according to claim 20,
wherein at least one of a plurality of the first electrodes included in the plurality of pixel circuits overlaps the capacitance wiring line including the opening in a plan view.

23. The display device according to claim 20,
wherein a plurality of the capacitance wiring lines each including the opening are formed in parallel to each other, and
at least one of a plurality of the first electrodes included in the plurality of pixel circuits overlaps both of two capacitance wiring lines located close to each other in a plan view.

24. The display device according to claim 20,
wherein at least one of a plurality of the first electrodes included in the plurality of pixel circuits overlaps the control electrode of the driving transistor in a plan view.

25. The display device according to claim 20,
wherein the control electrode of the driving transistor is formed two-dimensionally, and
at least one of a plurality of the first electrodes included in the plurality of pixel circuits overlaps all control electrodes of two driving transistors located close to each other in a plan view.

26. A display device comprising:
a display portion including a plurality of scanning lines, a plurality of data lines, and a plurality of pixel circuits;
a scanning line drive circuit configured to drive the plurality of scanning lines; and
a data line drive circuit configured to drive the plurality of data lines,
wherein each of the plurality of pixel circuits includes
an electro-optical element provided on a path connecting a first electrical conductive member and a second electrical conductive member and configured to emit light at brightness according to a current flowing through the path, the first electrical conductive member and the second electrical conductive member supplying a power source voltage, and
a driving transistor provided in series with the electro-optical element on the path and configured to control an amount of current flowing through the path, wherein a control electrode of the driving transistor is connected to a connection wiring line formed in a wiring line layer closer to a wiring line layer in which a first electrode of the electro-optical element is formed than a wiring line layer in which the control electrode of the driving transistor is formed,
the first electrode of the electro-optical element does not overlap the connection wiring line in a plan view,
each of the plurality of pixel circuits further includes a capacitance wiring line formed in a wiring line layer between the wiring line layer in which the control electrode of the driving transistor is formed and the wiring line layer in which the connection wiring line is formed,
the capacitance wiring line overlaps the control electrode of the driving transistor in a plan view and includes an opening in a part of a position overlapping the control electrode of the driving transistor,
the control electrode of the driving transistor and the connection wiring line are connected to each other through a contact hole formed in the opening, and
at least one of a plurality of the first electrodes included in the plurality of pixel circuits overlaps the control electrode of the driving transistor in a plan view.

27. The display device according to claim 26,
wherein the control electrode of the driving transistor is formed two-dimensionally, and
at least one of a plurality of the first electrodes included in the plurality of pixel circuits overlaps all control electrodes of two driving transistors located close to each other in a plan view.
